(19) United States
(12) Patent Application Publication
(10) Pub. No.: US 2008/0142774 A1
(43) Pub. Date: Jun. 19, 2008

(54) Integrated Circuit Having Resistive Memory

(75) Inventors: Andreas Walter, Dresden (DE); Thomas Weitz, Bad Duerkheim (DE); Reimund Engl, Regensburg (DE); Recai Sezi, Roettenbach (DE); Anna Maltenberger, Leutenbach (DE); Joerg Schumann, Dresden (DE)

Correspondence Address: DICKE, BILLIG & CZAJA, PLLC, FIFTH STREET TOWERS, 100 SOUTH FIFTH STREET, MINNEAPOLIS, MN, 55402, US

(73) Assignee: QIMONDA AG, Muenchen (DE)

(21) Appl. No.: 11/572,950

(22) PCT Filed: Jul. 20, 2005
(86) PCT No.: PCT/DE2005/001277

§ 371 Date: Jan. 25, 2008

(30) Foreign Application Priority Data
Jul. 30, 2004 (DE) 10 2004 037 150.4

(51) Int. Cl. H01L 45/00; H01L 51/40; H01L 51/30

(52) U.S. Cl. 257/4; 438/99; 257/E45.002; 257/E51.025

(57) ABSTRACT

An integrated circuit having resistive memory is disclosed. In one embodiment, the memory includes novel memory cells which have two electrodes and a layer arranged in between and including an active material which contains [1,2]dithiolo[4,3-[c]-1,2-dithiol-3,6-dithione, (2,4,7-trinitro-9-fluorenylidene)malonodinitrile and a polymer are disclosed. In one embodiment, a process for the production of the cells according to the invention is provided, as well as the novel use of a composition which can be used as active material for the memory cells.

### BACKGROUND

The invention relates to a semiconductor arrangement having a resistive memory for low-voltage applications.

One of the efforts in the further development of modern storage technologies is the increase of the integration density, so that the reduction in the structure sizes of the memory cells on which the memory devices are based is very important. Further efforts consist in developing novel memory cells which can be switched at relatively low voltages.

A plurality of microelectronic elements and in particular memory cells which have a size of a few nanometres has been described in recent years. A concept for designing such memory cells is to arrange, between two electrodes, an active layer which can reversibly change certain properties, such as, for example, ferromagnetic properties or electrical resistance, depending on the voltage. Depending on the applied voltage, the cell can be switched between two states, so that one state can be assigned, for example, to the information state “0” and the other state can be assigned to the information state “1”.

Various memory cells having an active layer have been described in the prior art.

Compared with the cells which have a ferroelectric material between two electrodes, the cell which has, between two electrodes, an active layer which can change the electrical resistance depending on the applied voltage has the advantage that it has a higher signal ratio between the OFF and ON state and need not be rewritten after the read process, since the reading of the state is not destructive.

Bandyopdhyay et al.: Applied Physics Letters, Vol. 82, pages 1215-1217 “Large conductance switching memory effects in organic molecules for data-storage applications” describe an active layer arranged between two electrodes and consisting of rose Bengal (4,5,6,7-tetrachloro-2′,4′,5′,7′-tetraiodofluorescein) with a polyallylamine hydrochloride polymer. The electrode consists of indium tin oxide on glass. The production of the active layer is, however, very inconvenient and requires treatment in an oven for several hours in vacuo. In addition, the active layer is limited to the indium tin oxide electrode.

A further memory cell having an active material which exhibits switchable behaviour is described in Yang et al.: Applied Physics Letters, Vol. 80, 2002, pages 2997-2999 “Organic Electrical Bistable Devices and Rewritable Memory Cells”. The active material consists of 2-amino-4,5-imidazoledicarbonitrile (AIDCN). The memory cell according to this prior art consists of a plurality of layers which have the following composition: an aluminium alloy deposited on glass, an AIDCN layer arranged thereon, a metal layer, a further AIDCN layer and a cathode. For switchability, this system requires the five layers described above, which makes the production very complex. A further disadvantage of the cells according to this prior art is that the cells can be switched only with aluminium electrodes and that the active layer can be applied only by vacuum vapour deposition.

For these and other reasons, there is a need for the present invention.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

One embodiment provides an integrated circuit, memory arrangement, memory, and memory cells. In one embodiment, the memory cells have an active layer arranged between two electrodes, the memory cells permitting a high integration density, being capable of being switched between two stable states of different electrical resistance, being easy to process by conventional methods in microelectronics and allowing the use of the electrodes customary in microelectronics.

Another embodiment is to propose memory cells which can be switched at very low voltage.

Another embodiment is to propose novel active materials which can be used in the memory cells.

One embodiment is achieved by a memory cell having two electrodes and an active layer arranged in between, the active layer including (a) [1,2]dithiolo-[4,3-c]-1,2-dithiol-3,6-dithione, (b)(2,4,7-trinitro-9-fluorenylidene)malonodinitrile and optionally (c) a polymer.

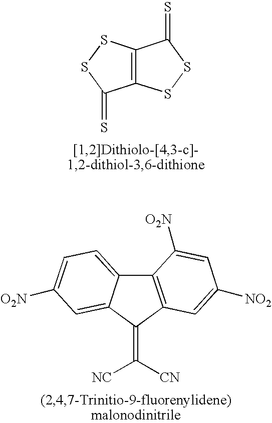

Advantages of the cell design according to the invention include reversible switchability, a ratio of the ON to OFF resistances of 10 or more, nondestructive reading since there is no necessity of rewriting after reading, nonvolatile information storage, functionality down to film thicknesses of about 20 nm, high thermal stability, switchability in the presence of air and moisture, simple and economical design of the cell and suitability of the memory cell for production in a plurality of layers, such as, for example, by the copper damascene technique.

The ratio of the component (a) to (b) can be varied within wide ranges. In a particular embodiment, the ratio of (a) to (b) is in the range from 1:4 to 4:1.

The amount by weight of the polymer, based on the total amount of the active material, is in the range from 0 to 70% by weight.

In a particular embodiment, the amount by weight of the polymer, based on the total amount of the active material, is in the range from 25 to 60% by weight.

The optionally used polymer serves as a film-forming carrier material and is not of decisive importance for the activity of the active material. In general, it is possible to use any polymer which has electronically insulating properties and is compatible with the components (a) and (b).

Polymers are, for example, polyether, polyacrylates, polyether sulphone, polyether sulphide, polyether ketone, polyquinolines, polyquinoxalines and polybenzoxazoles, polybenzimidazoles or polyimides or precursors thereof.

The polymer may be in the form of either a homopolymer or a copolymer having further polymerizable repeating units. The polymer may be present alone or as a blend of different polymers.

The substrate on which the electrodes have been applied or in which the electrodes were incorporated may be silicon, germanium, gallium arsenide or gallium nitride or any desired material which contains any desired compound of silicon, germanium or gallium. Furthermore, the substrate may also be a polymer, i.e. plastic, which is filled or unfilled or is present as a moulding or film, and may be ceramic, glass or metal. The substrate may also be a preprocessed material and contain one or more layers of contacts, conductor tracks, insulating layers and further microelectronic components.

In one embodiment, the substrate is silicon which has already been processed according to front-end-of-line (FEOL), i.e. already contains electric components, such as transistors, capacitors, etc.—manufactured by the silicon technique. An insulating layer is present between the substrate and the nearest electrode, particularly when the substrate is electrically conductive. However, it is also possible for a plurality of layers to be present between the substrate and the nearest electrode.

The substrate may serve as carrier material or may perform an electrical function (evaluation, control). For the last-mentioned case, there are electrical contacts between the substrate and the electrodes which are applied to the substrate. These electrical contacts are, for example, contact holes (vias) filled with an electrical conductor. However, it is possible for the contacts to be effected from the lower into the upper layers by metallization in the edge regions of the substrate or of the chips.

The active layer according to the invention is compatible with a multiplicity of electrodes conventionally used in microelectronics. Electrodes consist of Cu, Al, AlCu, AlSiCu, Ti, TiN, Ta, TaN, W, TiW, TaW, WN, WCN and customary combinations of these electrodes. Furthermore, thin layers of silicon, titanium silicon nitride, silicon oxynitride, silicon oxide, silicon carbide, silicon nitride or silicon carbonitride may also be present in combination with the abovementioned layers or materials.

The abbreviations, such as, for example, TiN, do not reproduce an exact stoichiometric ratio since the ratio of the components can be changed as desired within possible limits.

Various methods are suitable for depositing the abovementioned electrode layers. These may be, for example, PVD, CVD, PECVD, vapour deposition, electroplating, electroless plating or atomic layer deposition (ALCVD). However, the methods are not limited to these and it is in principle possible to use all methods used in microelectronics for the production of electrodes.

The deposition of the electrode can be effected from the gas phase or from solution.

The electrodes can be structured by various customary techniques. The structuring can be effected, for example, by hole masks, printing techniques or lithography. In particular, screen printing, microcontact printing and nanoimprinting are printing techniques.

However, the electrodes can also be structured, for example, by the damascene technique. For this purpose, for example, an insulating layer (preferably of silicon oxide) present above the substrate is structured by lithography and etching. After stripping of the photoresist, the electrode layer is deposited so that the trenches or holes in the insulating layer which are formed during the structuring are completely filled with the electrode materials. A part of these materials which projects above the surface of the insulating layer is then ground back. The grinding process can be effected by the CMP technique (chemical mechanical planarization). This results in, for example, conductor tracks and/or contact holes which are filled with the electrode materials and embedded in the insulating layer so that they have the same height as the insulating layer.

After the active material is deposited onto the electrode, the top electrode can be produced in exactly the same way as the bottom one. In one embodiment of the invention, the upper conductor tracks are arranged transversely to the lower conductor tracks. Thus, a crosspoint cell, which consists of three layers, namely bottom electrode, active material and top electrode, forms at each point of intersection of the top electrode with the bottom electrode.

The lateral geometry of the cell is not limited to the abovementioned crosspoint arrangement; since, however, the crosspoint arrangement permits a very high integration density, it is preferred for the present invention.

The above-described sandwich structures of the memory cells, consisting of two electrodes and the layer present in between and having the active material, can be applied to the substrate not just once but several times in a form stacked one on top of the other. This results in a plurality of planes for the memory cells, each plane consisting of two electrodes and the layer present in between and having the active material. It is of course also possible for a plurality of cells to be in a plane (cell array). The various planes can be separated from one another by an insulator, or it is also possible to use not four but three electrodes for two planes located one on top of the other, since it (middle electrode) can serve as the top electrode for the lower plane and as the bottom electrode for the upper plane.

The active material can be applied to the electrode, for example, by preparation of a solution which contains the components (a) and (b) and optionally a polymer. Suitable solvents are, for example, N-methylpyrrolidone, γ-butyrolactone, methoxypropyl acetate, ethoxyethyl acetate, cyclohexanone, cyclopentanone, ethers of ethylene glycol, such as diethylene glycol diethyl ether, ethoxyethyl propionate or ethyl lactate. A mixture of the abovementioned solvents with optionally further solvents can also be used as the solvent. The formulation may also contain additives, such as, for example, adhesion promoters (for example silanes).

The active material can, however, also be applied by vacuum vapour deposition. For this purpose, the components (a) and (b) are deposited simultaneously on the electrode (co-evaporation) or the components are applied directly in succession and thus form the active layer without a polymer.

After spin coating or vacuum vapour deposition, a heating process is effected in each case, for example on a hotplate or in an oven, in order to dry the film or optionally to complete the reaction, particularly when the components (a) and (b) are deposited on the electrode by vacuum vapour deposition. In the case of vacuum vapour deposition, the thermal treatment can, however, also be carried out in a vacuum chamber or even omitted.

The thickness of the layer which contains the active material is in the range of from between 20 and 2000 nm, the range between 20 and 200 nm being particularly preferred.

The advantages of the cell according to the invention are that the layer can be switched at very low voltages which are less than one volt, which is compatible with the future memory designs and permits only a low energy consumption.

The further advantage is that the design of the cell is very simple so that the production can be effected economically. The cell has a reversible, reproducible switchability under various conditions, such as, for example, in the presence of air and moisture and in a wide temperature range.

The adhesion of the layer to the electrodes is outstanding and the ratio of the state with higher resistance to the state of low resistance is higher than 10. The production can be effected by customary lithograph processes since the active layer is compatible with a multiplicity of processes. A particular advantage of the present cell is that the active layer is compatible with customary electrodes. The active layer is switchable with the electrodes and electrode combinations which are used in microelectronics, and the fact that the switchability is very reliable particularly with copper should be emphasized. This is important because copper has the lowest electrical resistance compared with the other electrical conductors which are used as standard in electronics. The production of the cell according to the invention is explained in more detail with reference to examples.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

1. A memory cell reversibly switchable between different stable electrical resistance states, the memory cell comprising a first electrode and a second electrode and an active layer which is arranged between the first and the second electrode, the active layer comprising:
[1,2]dithiolo-[4,3-c]-1,2-dithiol-3,6-dithione; and
(2,4,7-trinitro-9-fluorenylidene)malonodinitrile.

2.-14. (canceled)

15. The memory cell of claim 1 wherein the ratio of [1,2]dithiolo-[4,3-c]-1,2-dithiol-3,6-dithione to (2,4,7-trinitro-9-fluorenylidene)malonodinitrile is as low as 1:4 to as high as 4:1.

16. The memory cell of claim 1, wherein the active layer further comprises a polymer, the concentration of the polymer in the active layer being as high as 70 weight percent, based on the total weight of the active layer.

17. The memory cell of claim 16 wherein the polymer comprises a homopolymer or a copolymer of, or based upon, polyether, polyether sulphone, polysulphone, polyether sulphide, polyether ketone, polyacrylate, polyquinoline, polyquinoxaline, polybenzoxazole, polybenzimidazole, polyimide, or any precursor of these.

18. The memory cell of claim 1 wherein the thickness of the active layer is as small as 20 nanometers to as large as 2000 nanometers.

19. The memory cell of claim 1 wherein the first electrode, the second electrode, or both the first electrode and the second electrode incorporate copper, aluminum, silicon, titanium, tantalum, tungsten, carbon, nitrogen, oxygen, or combinations of these.

20. The memory cell of claim 1 wherein the first electrode, the second electrode, or both the first electrode and the second electrode comprise aluminum, copper, silicon, titanium, tantalum, tungsten, AlCu, AlSiCu, SiON, SiO, SiN, SiC, SiCN, TiN, TiSiN, TaN, TiW, TaW, WN, WCN, or combinations of these.

21. An integrated circuit comprising memory, the memory comprising at least one memory cell of claim 1.

22. The integrated circuit of claim 21, the integrated circuit comprising a substrate in working relation with the first electrode or the second electrode of the memory cell, the substrate comprising silicon, germanium or gallium.

23. A memory cell comprising a first electrode and a second electrode and an active layer arranged in working relation with the first and the second electrode, the active layer comprising:

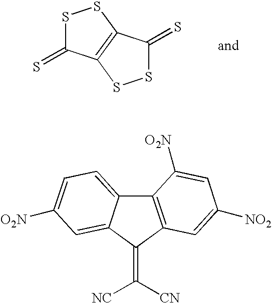

24. A method for manufacturing at least one memory cell that is reversibly switchable between different stable electrical resistance states, the method comprising generating a first electrode and a second electrode and depositing an active layer between the first electrode and the second electrode, the active layer comprising [1,2]dithiolo-[4,3-c]-1,2-dithiol-3,6-dithione and (2,4,7-trinitro-9-fluorenylidene)malonodinitrile.

25. The method of claim 24, the method further comprising incorporating the [1,2]dithiolo-[4,3-c]-1,2-dithiol-3,6-dithione and the (2,4,7-trinitro-9-fluorenylidene)malonodinitrile in the active layer via vacuum vapor deposition.

26. The method of claim 24, the method further comprising incorporating the [1,2]dithiolo-[4,3-c]-1,2-dithiol-3,6-dithione and the (2,4,7-trinitro-9-fluorenylidene)malonodinitrile in a solution and spin coating the solution to form the active layer.

27. The method of claim 24, the method further comprising setting the ratio of [1,2]dithiolo-[4,3-c]-1,2-dithiol-3,6-dithione to (2,4,7-trinitro-9-fluorenylidene)malonodinitrile from as low as 1:4 to as high as 4:1.

28. The method of claim 24, the method further comprising incorporating a polymer in the active layer.

29. The method of claim 28, the method further comprising setting the concentration of the polymer in the active layer as high as 70 weight percent, based on the total weight of the active layer.

30. The method of claim 28 wherein the polymer comprises a homopolymer or a copolymer of, or based upon, polyether, polyether sulphone, polysulphone, polyether sulphide, polyether ketone, polyacrylate, polyquinoline, polyquinoxaline, polybenzoxazole, polybenzimidazole, polyimide, or any precursor of these.

31. The method of claim 24, the method further comprising forming the active layer with a thickness from as small as 20 nanometers to as large as 2000 nanometers.

32. An method of using the memory cell of claim 1, the method comprising incorporating the memory cell in a memory arrangement of an integrated circuit that comprises a substrate in working relation with the first electrode or the second electrode of the memory cell.

33. The method of claim 32 wherein the substrate comprises silicon, germanium or gallium.
